(19) United States
(12) Patent Application Publication
(10) Pub. No.: US 2021/0265237 A1
(43) Pub. Date: Aug. 26, 2021

(54) SEMICONDUCTOR DEVICE AND METHOD FOR PRODUCING SEMICONDUCTOR DEVICE

(71) Applicant: SUMITOMO ELECTRIC INDUSTRIES, LTD., Osaka (JP)

(72) Inventors: Tatsuya HASHINAGA, Osaka (JP); Yutaka MORIYAMA, Osaka (JP)

(21) Appl. No.: 17/177,330

(22) Filed: Feb. 17, 2021

(30) Foreign Application Priority Data
Feb. 20, 2020 (JP) 2020-027411
Nov. 30, 2020 (JP) 2020-198532

(51) Int. Cl. H01L 23/373; H01L 23/31; H01L 21/48; H01L 21/288; H01L 29/16; H01L 21/56

(52) U.S. Cl. CPC H01L 23/3736; H01L 23/3114; H01L 21/4871; H01L 21/56; H01L 29/1608; H01L 21/4846; H01L 21/2885

(57) ABSTRACT

A semiconductor device includes an insulating substrate having a first surface, a semiconductor chip that is embedded in the insulating substrate and has a second surface exposed in the first surface, and a heat dissipation layer that is in contact with the first surface and the second surface and has a plated layer.

### CROSS-REFERENCE TO RELATED APPLICATION

The present application is based upon and claims priority to Japanese Patent Application No. 2020-027411, filed on Feb. 20, 2020 and Japanese Patent Application No. 2020-198532, filed on Nov. 30, 2020, the entire contents of which are incorporated herein by reference.

### BACKGROUND OF THE INVENTION

The present disclosure relates to a semiconductor device and a method for producing a semiconductor device.

A semiconductor device having a structure in which a semiconductor chip is embedded in an insulating layer is known. In such a semiconductor device, a metal plate is attached as a heat sink for dissipation of heat generated from a semiconductor chip (Patent Document 1, for example).

### RELATED ART DOCUMENTS

### Patent Document

### [Patent Document 1] Japanese Patent Application Publication No. 2008-305937

### SUMMARY OF THE INVENTION

According to one aspect of the present embodiment, a semiconductor device includes an insulating substrate having a first surface, a semiconductor chip that is embedded in the insulating substrate and has a second surface exposed in the first surface, and a heat dissipation layer that is in contact with the first surface and the second surface and has a plated layer.

### BRIEF DESCRIPTION OF THE DRAWINGS

FIG. 1 is a cross-sectional view showing a structure of a semiconductor device according to a first embodiment.

FIG. 2 is a cross-sectional view showing a semiconductor device mounted on a mother substrate.

FIG. 3 is a cross-sectional view (No. 1) showing a first example of a method for producing a semiconductor device according to the first embodiment.

FIG. 4 is a cross-sectional view (No. 2) showing the first example of the method for producing a semiconductor device according to the first embodiment.

FIG. 5 is a cross-sectional view (No. 3) showing the first example of the method for producing a semiconductor device according to the first embodiment.

FIG. 6 is a cross-sectional view (No. 4) showing the first example of the method for producing a semiconductor device according to the first embodiment.

FIG. 7 is a cross-sectional view (No. 5) showing the first example of the method for producing a semiconductor device according to the first embodiment.

FIG. 8 is a cross-sectional view (No. 6) showing the first example of the method for producing a semiconductor device according to the first embodiment.

FIG. 9 is a cross-sectional view (No. 7) showing the first example of the method for producing a semiconductor device according to the first embodiment.

FIG. 10 is a cross-sectional view (No. 8) showing the first example of the method for producing a semiconductor device according to the first embodiment.

FIG. 11 is a cross-sectional view (No. 9) showing the first example of the method for producing a semiconductor device according to the first embodiment.

FIG. 12 is a cross-sectional view (No. 10) showing the first example of the method for producing a semiconductor device according to the first embodiment.

FIG. 13 is a cross-sectional view (No. 11) showing the first example of the method for producing a semiconductor device according to the first embodiment.

FIG. 14 is a cross-sectional view (No. 12) showing the first example of the method for producing a semiconductor device according to the first embodiment.

FIG. 15 is a cross-sectional view (No. 1) showing a second example of a method for producing a semiconductor device according to a second embodiment.

FIG. 16 is a cross-sectional view (No. 2) showing the second example of the method for producing a semiconductor device according to the second embodiment.

FIG. 17 is a cross-sectional view (No. 3) showing the second example of the method for producing a semiconductor device according to the second embodiment.

FIG. 18 is a cross-sectional view (No. 4) showing the second example of the method for producing a semiconductor device according to the second embodiment.

FIG. 19 is a cross-sectional view (No. 5) showing the second example of the method for producing a semiconductor device according to the second embodiment.

FIG. 20 is a cross-sectional view (No. 6) showing the second example of the method for producing a semiconductor device according to the second embodiment.

FIG. 21 is a cross-sectional view showing a structure of a semiconductor device according to a second embodiment.

FIG. 22 is a cross-sectional view (No. 1) showing a first example of a method for producing a semiconductor device according to a second embodiment.

FIG. 23 is a cross-sectional view (No. 2) showing the first example of the method for producing a semiconductor device according to the second embodiment.

FIG. 24 is a cross-sectional view (No. 3) showing the first example of the method for producing a semiconductor device according to the second embodiment.

FIG. 25 is a cross-sectional view (No. 4) showing the first example of the method for producing a semiconductor device according to the second embodiment.

FIG. 26 is a cross-sectional view (No. 5) showing the first example of the method for producing a semiconductor device according to the second embodiment.

FIG. 27 is a cross-sectional view (No. 6) showing the first example of the method for producing a semiconductor device according to the second embodiment.

FIG. 28 is a cross-sectional view (No. 1) showing a second example of a method for producing a semiconductor device according to the second embodiment.

FIG. 29 is a cross-sectional view (No. 2) showing the second example of the method for producing a semiconductor device according to the second embodiment.

FIG. 30 is a cross-sectional view (No. 3) showing the second example of the method for producing a semiconductor device according to the second embodiment.

### DESCRIPTION OF THE PREFERRED EMBODIMENTS

In a conventional semiconductor device, heat dissipation characteristics may vary.

It is an object of the present disclosure to provide a semiconductor device and a method for producing a semiconductor device in which stable heat dissipation characteristics are obtained.

Embodiments according to the present disclosure will be described below.

### Description of Embodiments of the Present Disclosure

First, the contents of embodiments according to the present disclosure will be listed and described. In the following description, the same or corresponding elements are denoted by the same reference numerals and redundant descriptions thereof will be omitted.

[1] A semiconductor device according to an aspect of the present disclosure includes an insulating substrate having a first surface, a semiconductor chip that is embedded in the insulating substrate and has a second surface exposed in the first surface, and a heat dissipation layer that is in contact with the first surface and the second surface and has a plated layer.

The present inventors have studied the causes of variation in heat dissipation characteristics in a conventional semiconductor device. As a result, it has been found that an unexpected gap may occur between a metal plate and an insulating layer. That is, although the metal plate is fixed to the insulating layer using a silver nano paste or the like, coating amount of the silver nano paste may vary and thus a gap may occur.

The semiconductor device according to the present disclosure is provided with a heat dissipation layer that is in contact with the first surface of the insulating substrate and the second surface of the semiconductor chip and has a plated layer. The heat dissipation layer with the plated layer can be formed without gaps between the first surface and the second surface. Therefore, stable heat dissipation characteristics can be obtained.

[2] In the semiconductor device described in the above [1], the heat dissipation layer may include a sputtered layer having a third surface in contact with the first surface and the second surface, and a fourth surface opposite to the third surface. The plated layer may include a fifth surface in contact with the fourth surface. In this case, the third surface is firmly bonded to the first surface and the second surface, and heat is transferred from the semiconductor chip to the heat dissipation layer with a high efficiency.

[3] In the semiconductor device described in the above [1] or [2], the semiconductor chip may include a silicon carbide substrate having the second surface, so that the semiconductor device is suitable for high-frequency applications.

[4] In the semiconductor device described in the above [1], the semiconductor chip may include a silicon carbide substrate, and a Cu layer in contact with the silicon carbide substrate and having the second surface, wherein the plated layer may have a fifth surface in contact with the first surface and the second surface. In this case, the fifth surface is firmly bonded to the first surface and the second surface, heat is transferred from the semiconductor chip to the heat dissipation layer with high efficiency, and the semiconductor device is suitable for high frequency applications.

[5] In the semiconductor device described in the above [1] to [4], the thickness of the heat dissipation layer may be 100 μm or more. In this case, particularly good heat dissipation characteristics are obtained.

[6] In the semiconductor device described in the above [1] to [5], a heat dissipation member may be attached to the heat dissipation layer. In this case, heat dissipation efficiency to the outside can be improved.

[7] A method for producing a semiconductor device according to another aspect of the present disclosure includes the steps of embedding a semiconductor chip having a second surface to be exposed in a first surface into an insulating substrate having the first surface, and forming a heat dissipation layer that is in contact with the first surface and the second surface and has a plated layer.

In the method according to the present disclosure, a heat dissipation layer is formed to have a plated layer and to be in contact with the first surface of the insulating substrate and the second surface of the semiconductor chip. Since the heat dissipation layer with the plated layer can be formed without gaps between the first surface and the second surface, stable heat dissipation characteristics can be obtained.

[8] In the method for producing a semiconductor device described in the above [7], the insulating substrate may include a first insulating layer and a second insulating layer, and the step of embedding the semiconductor chip may include the steps of forming a wiring layer on the first insulating layer, mounting the semiconductor chip on the wiring layer such that the second surface faces a direction opposite a direction towards the first insulating layer, forming the second insulating layer on the first insulating layer so as to cover the semiconductor chip, and providing the first surface in the second insulating layer by polishing the second insulating layer until the second surface is exposed. In this case, the first surface and the second surface can be easily made flush with each other.

[9] In the method for producing a semiconductor device described in the above [7] or [8], the step of forming the heat dissipation layer may include the steps of forming a sputtered layer having a third surface in contact with the first surface and the second surface, and a fourth surface opposite to the third surface, and forming a plated layer on the sputtered layer. The plated layer may include a fifth surface in contact with the fourth surface. In this case, the third surface is firmly bonded to the first surface and the second surface, and heat is transferred from the semiconductor chip to the heat dissipation layer with a high efficiency.

[10] In the method for producing a semiconductor device described in the above [9], the step of forming a plated layer may include the step of forming a first layer having the fifth surface on the sputtered layer by electroless plating. The first layer then has a good adhesion with the sputtered layer.

[11] In the method for producing a semiconductor device described in the above [7] or [8], the semiconductor chip may include a Cu layer having the second surface, and the step of forming a heat dissipation layer may include the step of forming the plated layer to be in contact with the first surface and the second surface. In this case, the plated layer is firmly bonded to the first surface and the second surface, and heat is transferred from the semiconductor chip to the heat dissipation layer with high efficiency.

[12] In the method for producing a semiconductor device described in the above [11], the step of forming a plated layer may include forming a first layer in contact with the first surface and the second surface by electroless plating. In this case, the first layer has a good adhesion between the first surface and the second surface.

[13] In the method for producing a semiconductor device described in the above [10] or [12], the step of forming a plated layer may include the step of forming a second layer on the first layer by electroplating. In this case, the second layer is more likely to be formed to be thicker than the first layer.

[14] In the method for producing a semiconductor device described in the above [13], the step of forming a plated layer may include the step of polishing the second layer. In this case, the uniformity of the thickness of the heat dissipation layer can be improved.

[15] In the method for producing a semiconductor device described in the above [13] or [14], the step of forming a plated layer may include the step of forming a third layer on the second layer by electroplating. In this case, the third layer may be formed under the conditions in which deposition rate is higher than that of the second layer, and excellent heat dissipation characteristics can be obtained in a short deposition time.

[16] A method for producing a semiconductor device according to another aspect of the present disclosure includes the steps of forming a wiring layer on a first insulating layer, mounting a semiconductor chip having a second surface on the wiring layer such that the second surface faces a direction opposite a direction towards the first insulating layer, forming a second insulating layer on the first insulating layer so as to cover the semiconductor chip, providing the first surface in the second insulating layer by polishing the second insulating layer until the second surface is exposed, forming a sputtered layer having a third surface in contact with the first surface and the second surface, and a fourth surface opposite to the third surface, and forming a plated layer having a fifth surface in contact with the fourth surface on the sputtered layer. The step of forming a plated layer may include steps of forming a first layer having the fifth surface on the sputtered layer by electroless plating, forming a second layer on the first layer by electroplating, polishing the second layer, and forming a third layer on the second layer by electroplating after the step of polishing the second layer.

[17] A method for producing a semiconductor device according to another aspect of the present disclosure includes forming a wiring layer on a first insulating layer; mounting a semiconductor chip including a Cu layer having a second surface on the wiring layer such that the second surface faces a direction opposite a direction towards the first insulating layer; forming a second insulating layer on the first insulating layer so as to cover the semiconductor chip; providing a first surface in the second insulating layer by polishing the second insulating layer until the second surface is exposed; and forming a plated layer to be in contact with the first surface and the second surface, wherein the forming the plated layer includes forming a first layer in contact with the first surface and the second surface by electroless plating, forming a second layer on the first layer by electroplating, polishing the second layer, and forming a third layer on the second layer by electroplating after the polishing the second layer.

### First Embodiment of Present Disclosure

A first embodiment according to the present disclosure relate to a semiconductor device.

### (Structure of Semiconductor Device)

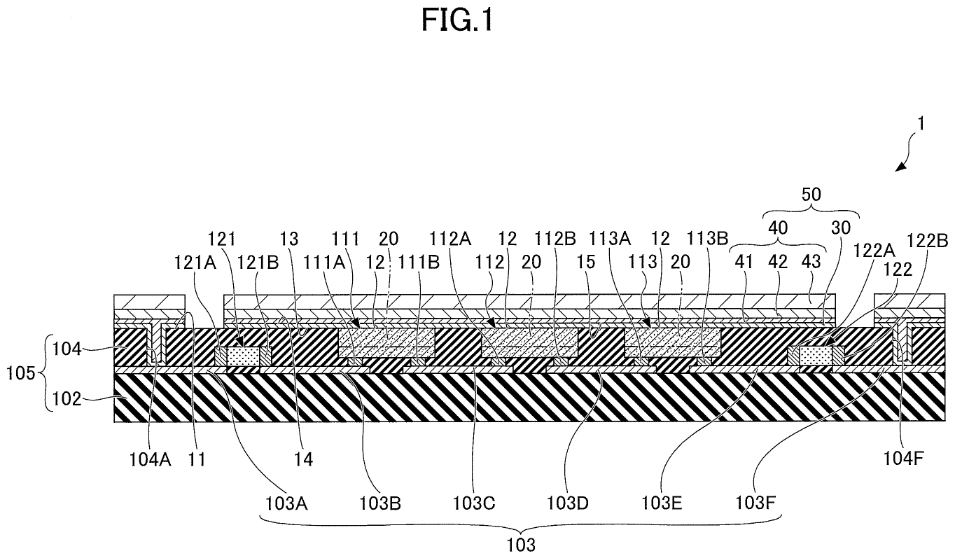

First, the structure of a semiconductor device according to a first embodiment will be described. FIG. 1 is a cross-sectional view showing the structure of a semiconductor device according to the first embodiment.

As shown in FIG. 1, in a semiconductor device 1 according to the first embodiment, a wiring layer 103 is formed on an insulating layer 102. The wiring layer 103 includes wirings 103A, 103B, 103C, 103D, 103E, and 103F, for example. The insulating layer 102 is a dry film having a thickness of 0.2 mm or more and 0.5 mm or less, for example. The insulating layer 102 is an example of the first insulating layer. The wiring layer 103 is a Cu layer having a thickness of 5 μm or more and 50 μm or less, for example.

Semiconductor chips 111, 112 and 113, and electronic components 121 and 122 are mounted on the wiring layer 103. The semiconductor chip 111 has an electrode 111A connected to the wiring 103B and an electrode 111B connected to the wiring 103C. The semiconductor chip 112 has an electrode 112A connected to the wiring 103C and an electrode 112B connected to the wiring 103D. The semiconductor chip 113 has an electrode 113A connected to the wiring 103D and an electrode 113B connected to the wiring 103E. Each of the semiconductor chips 111 to 113 includes a second surface 12 opposite to the insulating layer 102. The electronic component 121 has an electrode 121A connected to the wiring 103A and an electrode 121B connected to the wiring 103B. The electronic component 122 has an electrode 122A connected to the wiring 103E and an electrode 122B connected to the wiring 103F.

The semiconductor chips 111 to 113 may be integrated circuit chips, for example. The semiconductor chips 111 to 113 may include, for example, a driver amplifier, a final amplifier, or the like. The semiconductor chips 111 to 113 each include a silicon carbide substrate 20 with the second surface 12. In the semiconductor chips 111 to 113, an element such as a high electron mobility transistor (HEMT) is formed on a surface opposite to the second surface 12 of the silicon carbide substrate 20. The HEMT may include a nitride semiconductor such as gallium nitride. The semiconductor chips 111 to 113 are mounted on the wiring layer 103 with flip-chip bonding. The electronic components 121 and 122 may be capacitors, inductors, or resistive elements, for example.

An insulating layer 104 is formed on the insulating layer 102. The insulating layer 104 includes a first surface 11 opposite the insulating layer 102. The second surfaces 12 of the semiconductor chips 111 to 113 are exposed in the first surface 11. For example, the first surface 11 is preferably flush with the second surfaces 12. The insulating layer 104 is a dry film having a thickness of 0.2 mm or more and 0.5 mm or less, for example. The insulating layer 104 is an example of the second insulating layer.

The insulating layer 102 and the insulating layer 104 are included in an insulating substrate 105 with the first surface 11. The semiconductor chips 111 to 113 are embedded in the insulating substrate 105. The semiconductor device 1 has a heat dissipation layer 50 formed on the first surface 11 and the second surfaces 12. The thickness of the heat dissipation layer 50 is preferably 100 μm or more, more preferably 200 μm or more, and still more preferably 300 μm or more. This is to obtain an excellent thermal conductivity.

The heat dissipation layer 50 has a sputtered layer 30 with a third surface 13 in contact with the first surface 11 and the second surfaces 12. The sputtered layer 30 has a fourth surface 14 opposite to the third surface 13. The sputtered layer 30 includes, for example, a Pd layer, a Pt layer, a Cu layer, a Ni layer, or a Ti layer each having a thickness of 0.01 μm or more and 0.5 μm or less. The sputtered layer 30 may include at least two kinds of layers selected from the group consisting a Pd layer, a Pt layer, a Cu layer, a Ni layer, and a Ti layer.

The heat dissipation layer 50 has a plated layer 40 with a fifth surface 15 in contact with the fourth surface 14. The plated layer 40 includes, for example, an electroless plated layer 41, an electroplated layer 42, and an electroplated layer 43 that are stacked in this order on the sputtered layer 30. The electroless plated layer 41 has the fifth surface 15 and includes a Cu layer having a thickness of 0.1 μm or more and 10 μm or less, for example. The electroplated layer 42 includes a Cu layer having a thickness of 50 μm or more and 90 μm or less, for example. The electroplated layer 43 includes a Cu layer, for example. The total thickness of the sputtered layer 30, the electroless plated layer 41, and the electroplated layer 42 is preferably 100 μm or less, more preferably 80 μm or less, for example.

In the insulating layer 104, an opening 104A is formed so as to reach the wiring 103A from the first surface 11, and an opening 104F is formed so as to reach the wiring 103F from the first surface 11. Portions of the heat dissipation layer 50 are formed in the openings 104A and 104F.

The numbers of semiconductor chips and electronic components included in the semiconductor device 1 are not limited. Also, the types of semiconductor chips and electronic components are not limited.

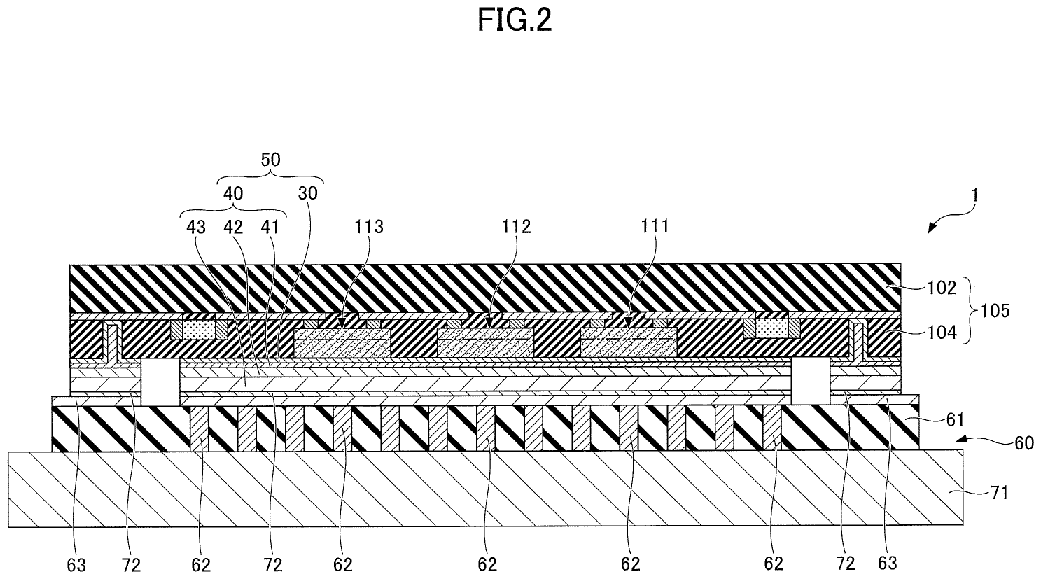

The semiconductor device 1 is used in a mounted state on a mother substrate, for example. FIG. 2 is a cross-sectional view showing a semiconductor device 1 mounted on a mother substrate.

As shown in FIG. 2, the mother substrate 60 includes a base substrate 61 having a plate-like shape, a plurality of conductive vias 62 penetrating through the base substrate 61 in the thickness direction, and a conductive pattern 63 formed on one surface of the base substrate 61. In the semiconductor device 1, the heat dissipation layer 50 is disposed so as to face the conductive pattern 63. Then, the heat dissipation layer 50 and the conductive pattern 63 are bonded to each other using a conductive bonding material 72 such as a solder or the like. Thus, portions of the heat dissipation layer 50 are electrically connected to the conductive vias 62.

The other side of the mother substrate 60 is bonded to a base metal 71. The conductive vias 62 are in contact with the base metal 71. Accordingly, when a ground potential is applied to the base metal 71, a ground potential is applied to the portions of the heat dissipation layer 50 which are electrically connected to the conductive vias 62.

The arithmetic average roughness (Ra) of the top surface of the heat dissipation layer 50 is preferably 2.0 μm or less, more preferably 1.6 μm or less, and still more preferably 1.0 μm or less. This is to provide the conductive bonding material 72 between the heat dissipation layer 50 and the conductive pattern 63 without gaps. In order to obtain the above arithmetic average roughness (Ra) of the top surface of the heat dissipation layer 50, the arithmetic average roughness (Ra) of the top surface of the electroplated layer 42 is preferably 2.0 μm or less, more preferably 1.6 μm or less, and still more preferably 1.0 μm or less. In order to obtain the above arithmetic average roughness (Ra) of the top surface of the electroplated layer 42, the arithmetic average roughness (Ra) of the first surface 11 is preferably 2.0 μm or less, more preferably 1.6 μm or less, and still more preferably 1.0 μm or less.

### First Example of a Method for Producing a Semiconductor Device

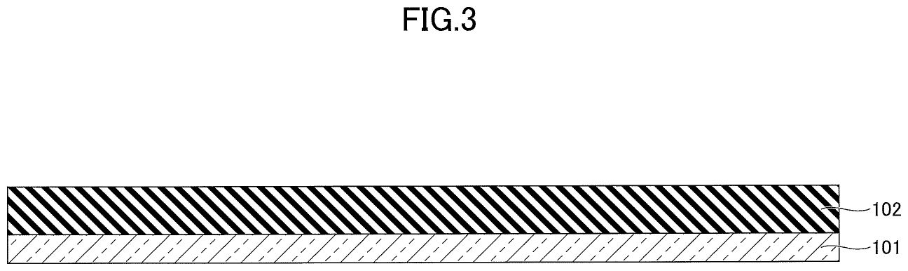

Next, a first example of a method for producing a semiconductor device according to the first embodiment will be described. FIGS. 3 to 14 are cross-sectional views showing the first example of a method for producing a semiconductor device according to the first embodiment.

First, as shown in FIG. 3, a substrate 101 is prepared to form an insulating layer 102 on the substrate 101. For example, a dry film is laminated on the substrate 101 as the insulating layer 102. A glass substrate can be used as the substrate 101, for example. The substrate 101 is sized to produce a plurality of semiconductor devices 1. For example, the thickness of the substrate 101 is 0.1 mm or more and 3.0 mm or less, and the length in the longitudinal direction and the length in the lateral direction of the substrate 101 are both 500 mm or more and 700 mm or less. In the substrate 101, a product region for each semiconductor device 1 is set, and a dicing region is set between the adjacent product regions. The product region and the dicing region are taken over to various layers formed on the substrate 101.

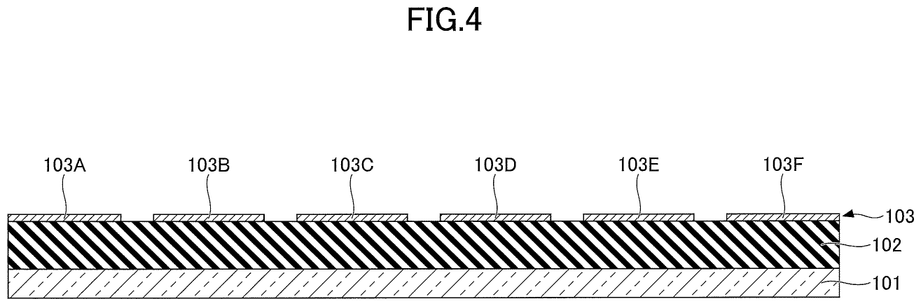

A wiring layer 103 is then formed on the insulating layer 102 as shown in FIG. 4. The wiring layer 103 includes wirings 103A, 103B, 103C, 103D, 103E, and 103F, for example. The wiring layer 103 can be formed by a semi-additive method, for example.

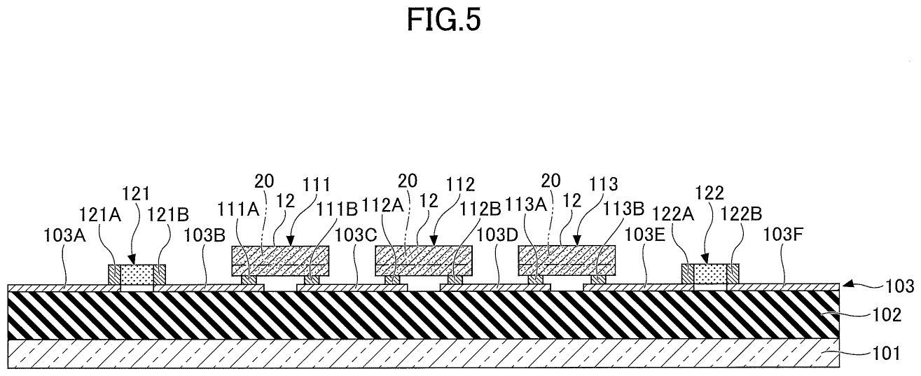

Semiconductor chips 111, 112, and 113 are then mounted on the wiring layer 103, as shown in FIG. 5. At this time, the semiconductor chips 111 to 113 are mounted so that each second surface 12 faces the direction opposite the direction towards the insulating layer 102. That is, the semiconductor chips 111, 112 and 113 are mounted with a flip-chip bonding method. For example, an electrode 111A of the semiconductor chip 111 is connected to the wiring 103B, and an electrode 111B is connected to the wiring 103C. For example, an electrode 112A of the semiconductor chip 112 is connected to the wiring 103C, and an electrode 112B is connected to the wiring 103D. For example, an electrode 113A of the semiconductor chip 113 is connected to the wiring 103D, and an electrode 113B is connected to the wiring 103E.

Also, as shown in FIG. 5, electronic components 121 and 122 are mounted on the wiring layer 103. For example, an electrode 121A of the electronic component 121 is connected to the wiring 103A, and an electrode 121B is connected to the wiring 103B. For example, an electrode 122A of the electronic component 122 is connected to the wiring 103E, and an electrode 122B is connected to the wiring 103F.

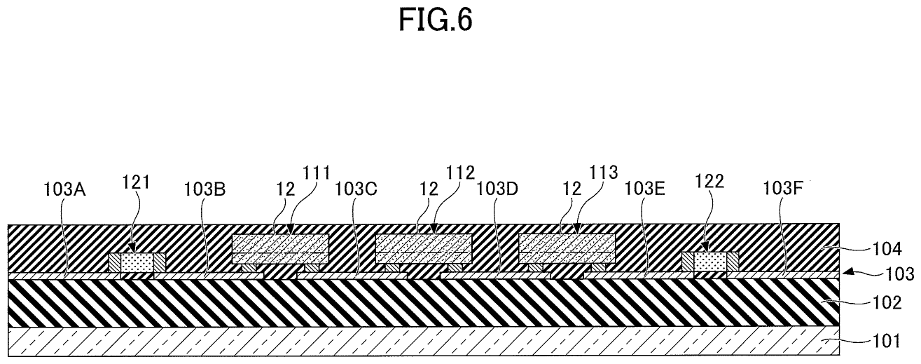

Next, as shown in FIG. 6, an insulating layer 104 is formed on the insulating layer 102 so as to cover the semiconductor chips 111 to 113 and the electronic components 121 to 122. For example, a dry film is laminated on the insulating layer 102 as the insulating layer 104.

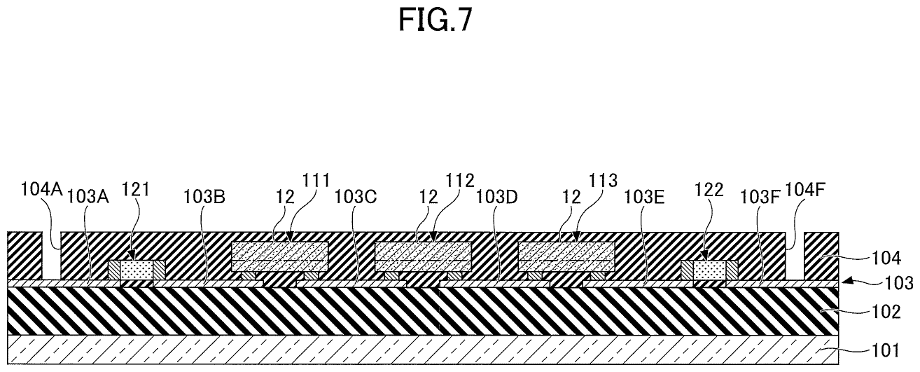

As shown in FIG. 7, an opening is then formed in the insulating layer 104 so as to reach a part of the wiring layer 103. For example, an opening 104A reaching the wiring 103A and an opening 104F reaching the wiring 103F are formed in the insulating layer 104.

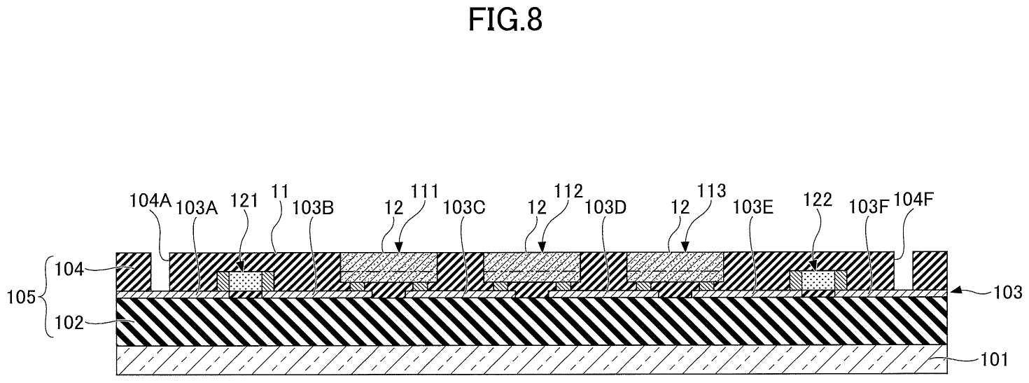

Next, as shown in FIG. 8, the top surface of the insulating layer 104 is polished until each of the second surfaces 12 of the semiconductor chips 111 to 113 is exposed. As a result, a first surface 11 is provided in the insulating layer 104. The arithmetic average roughness (Ra) of the first surface 11 is preferably 2.0 μm or less, more preferably 1.6 μm or less, and still more preferably 1.0 μm or less. This is to obtain an excellent flatness of a heat dissipation layer 50 to be formed later. The first surface 11 is preferably flush with the second surfaces 12. The insulating layer 102 and the insulating layer 104 are included in an insulating substrate 105 having the first surface 11.

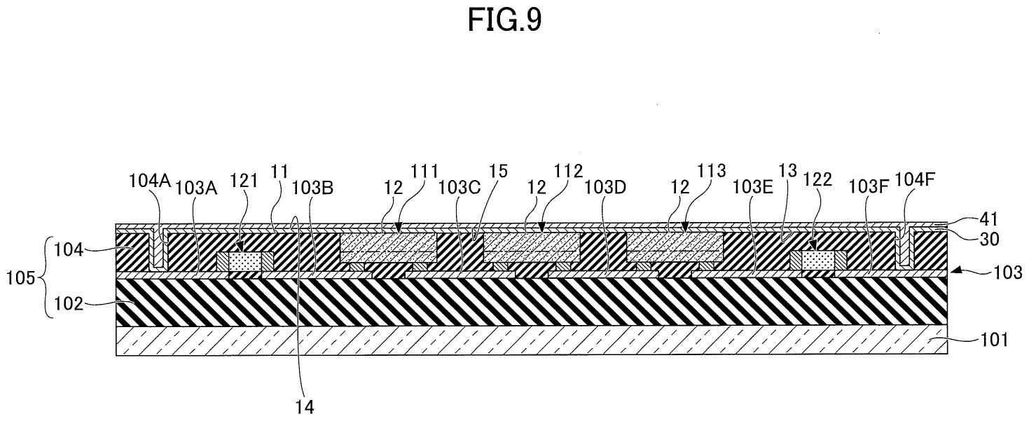

Next, as shown in FIG. 9, a sputtered layer 30 is formed on the top surface of the insulating layer 104 and the inner wall and bottom surfaces of the openings 104A and 104F by a sputtering method. The sputtered layer 30 is, for example, a Pd layer, a Pt layer, a Cu layer, a Ni layer, or a Ti layer each having a thickness of 0.01 μm or more and 0.5 μm or less. As the sputtered layer 30, a stacked body including at least two kinds of layers selected from the group consisting a Pd layer, a Pt layer, a Cu layer, a Ni layer, and a Ti layer may be formed. The sputtered layer 30 has a third surface 13 in contact with the first surface 11 and the second surfaces 12, and a fourth surface 14 opposite to the third surface 13. Prior to forming the sputtered layer 30, a desmear treatment may be performed to the top surface of the insulating layer 104 and the inner wall and bottom surfaces of the openings 104A and 104F.

An electroless plated layer 41 is then formed on the sputtered layer 30 by electroless plating, as also shown in FIG. 9. The electroless plated layer 41 includes a fifth surface 15 in contact with the fourth surface 14. As the electroless plated layer 41, for example, a Cu layer having a thickness of 5 μm or more and 10 μm or less is formed. The electroless plated layer 41 is an example of the first layer.

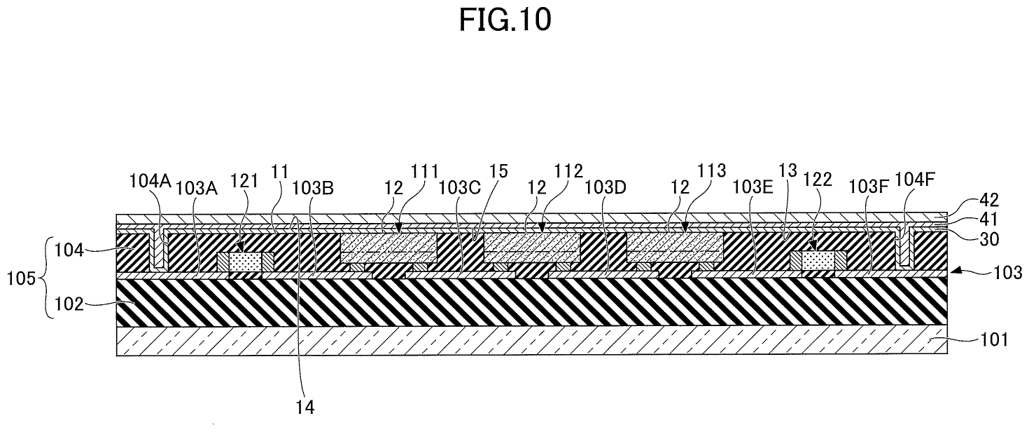

Next, an electroplated layer 42 is formed on the electroless plated layer 41 by electroplating, as shown in FIG. 10. As the electroplated layer 42, for example, a Cu layer having a thickness of 50 μm or more and 90 μm or less is formed. Thereafter, the top surface of the electroplated layer 42 is polished. The arithmetic average roughness (Ra) of the top surface of the electroplated layer 42 is preferably set to 2.0 μm or less, more preferably set to 1.6 μm or less, and still more preferably set to 1.0 μm or less. This is to obtain an excellent flatness of an electroplated layer 43 to be formed later. For example, the total thickness of the sputtered layer 30, the electroless plated layer 41, and the electroplated layer 42 is preferably set to 100 μm or less, more preferably 80 μm or less. This is because it takes time to form these layers. The electroplated layer 42 is an example of the second layer.

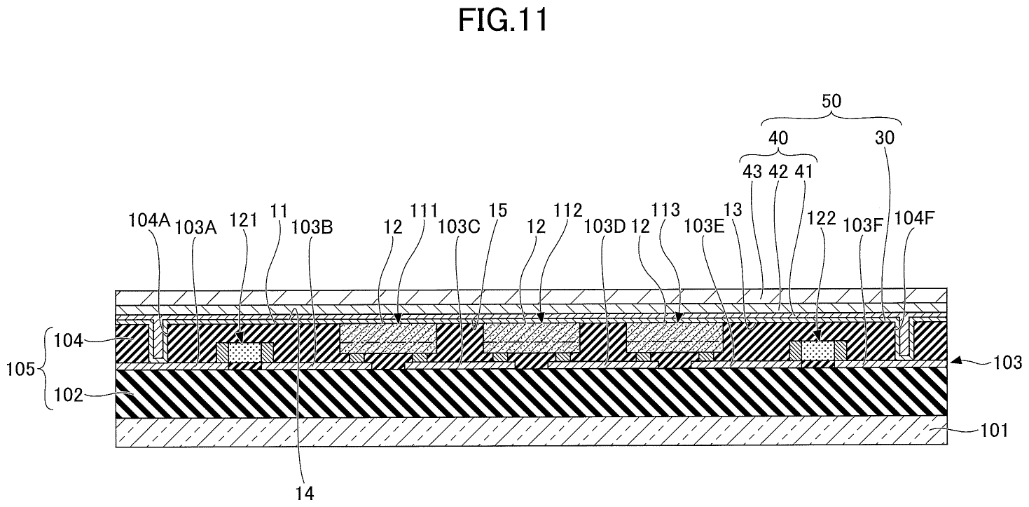

An electroplated layer 43 is then formed on the electroplated layer 42 by electroplating, as shown in FIG. 11. As the electroplated layer 43, for example, a Cu layer is formed. The electroplated layer 43 is preferably formed at a deposition rate of 50 μm/hour or more, and more preferably at a deposition rate of 60 μm/hour or more. The electroless plated layer 41, the electroplated layer 42, and the electroplated layer 43 are included in the plated layer 40. The sputtered layer 30 and the plated layer 40 are included in the heat dissipation layer 50. The thickness of the heat dissipation layer 50 is preferably 100 μm or more, more preferably 200 μm or more, and still more preferably 300 μm or more. The electroplated layer 43 is an example of the third layer.

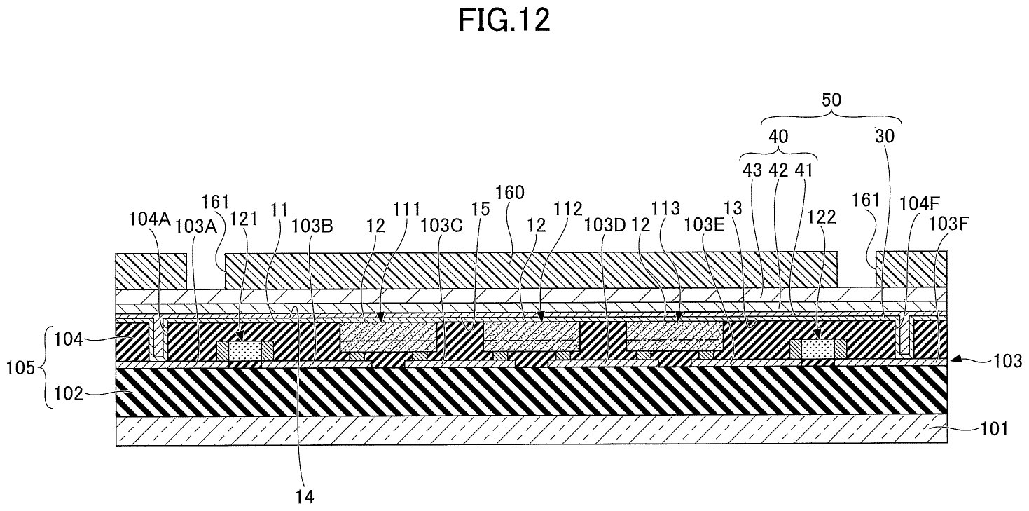

Next, as shown in FIG. 12, an etching mask 160 is formed on the heat dissipation layer 50. The etching mask 160 has openings 161 on the portions from which the heat dissipation layer 50 is to be removed. The etching mask 160 is formed by photoresist coating, exposure, and development, for example.

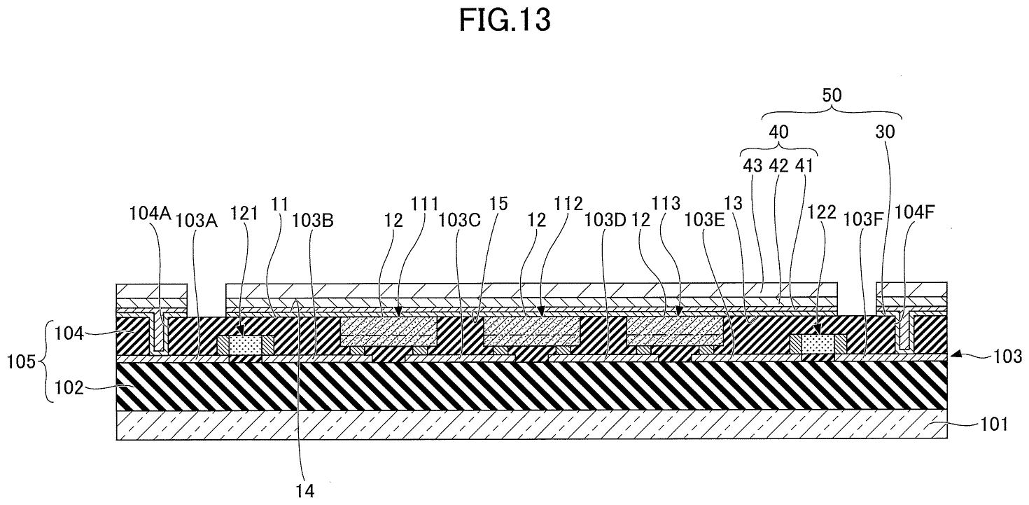

The heat dissipation layer 50 is then etched using the etching mask 160. As a result, as shown in FIG. 13, the portions of the heat dissipation layer 50 exposed in the openings 161 are removed. Thereafter, the etching mask 160 is removed.

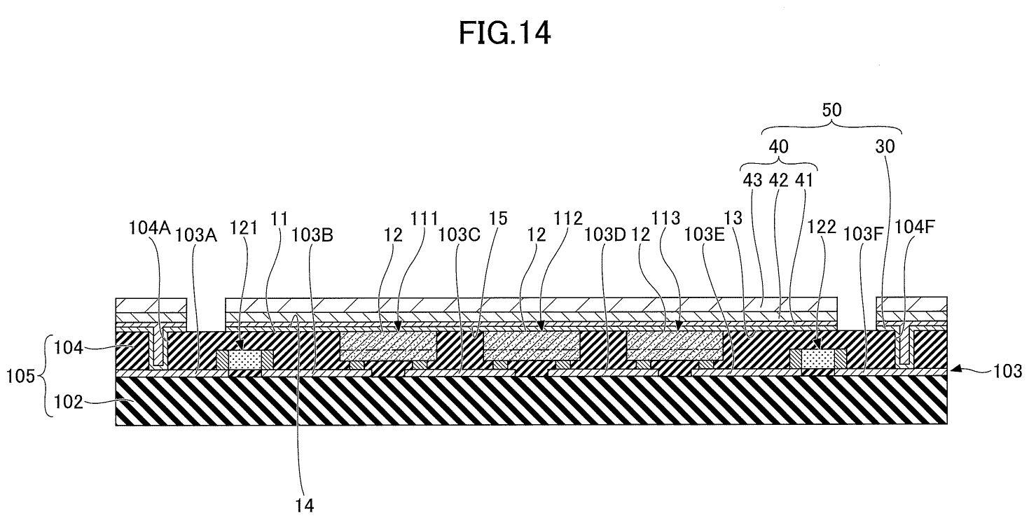

The substrate 101 is then removed, as shown in FIG. 14. Thereafter, the structure shown in FIG. 14 is cut along a dicing region to be separated into a plurality of semiconductor devices 1.

In this manner, the semiconductor device 1 according to the first embodiment can be obtained.

### Second Example of a Method for Producing a Semiconductor Device

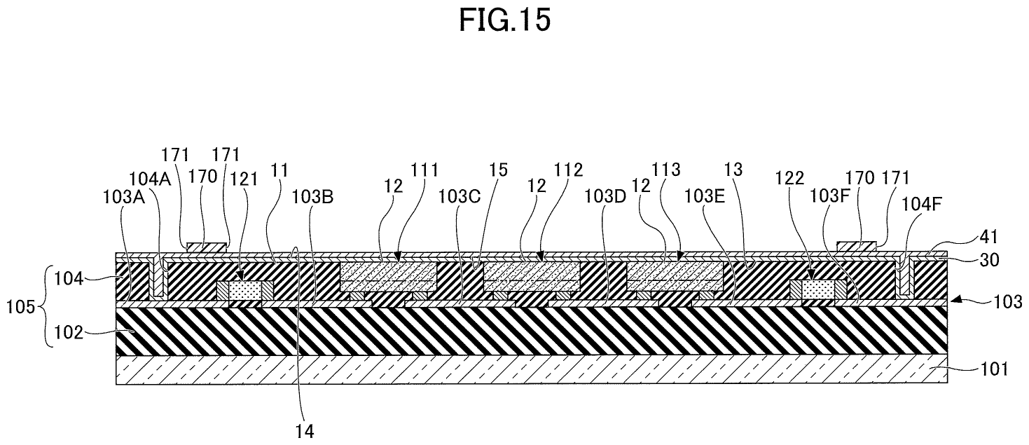

Next, the second example of a method for producing a semiconductor device according to the first embodiment will be described. FIGS. 15 to 20 are cross-sectional views showing the second example of a method for producing a semiconductor device according to the first embodiment.

First, as shown in FIG. 15, in the same manner as in the first example, the steps up to the forming of an electroless plated layer 41 is performed. Next, a growth mask 170 is formed on the electroless plated layer 41. The growth mask 170 has openings 171 on the portions on which a heat dissipation layer 50 is to be formed. The growth mask 170 is formed, for example, by photoresist coating, exposure, and development. For example, the thickness of the growth mask 170 may be similar to the thickness of an electroplated layer 42 to be formed later.

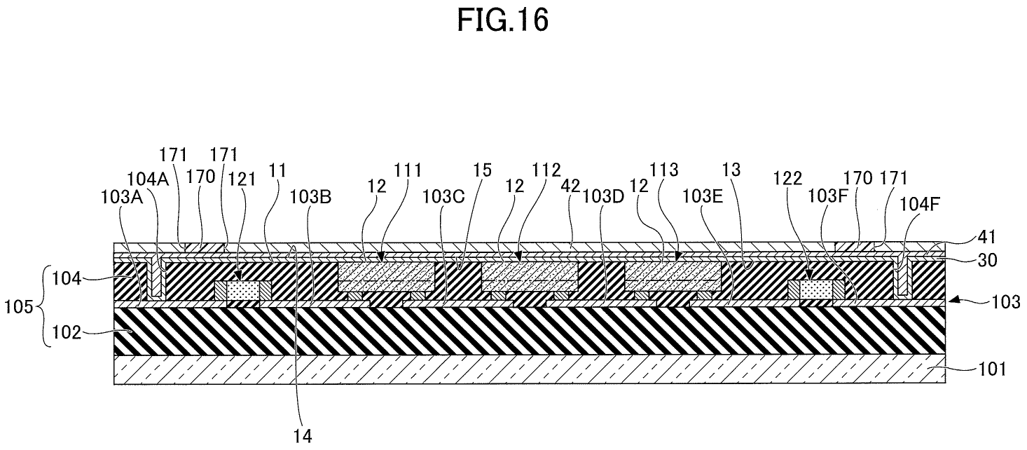

An electroplated layer 42 is then formed on the portion of the electroless plated layer 41 exposed in the openings 171 by electroplating, as shown in FIG. 16. As the electroplated layer 42, for example, a Cu layer having a thickness of 50 μm or more and 90 μm or less is formed. The top surface of the electroplated layer 42 is then polished. The arithmetic average roughness (Ra) of the top surface of the electroplated layer 42 is preferably set to 2.0 μm or less, more preferably set to 1.6 μm or less, and still more preferably set to 1.0 μm or less. The growth mask 170 may be polished simultaneously with the electroplated layer 42.

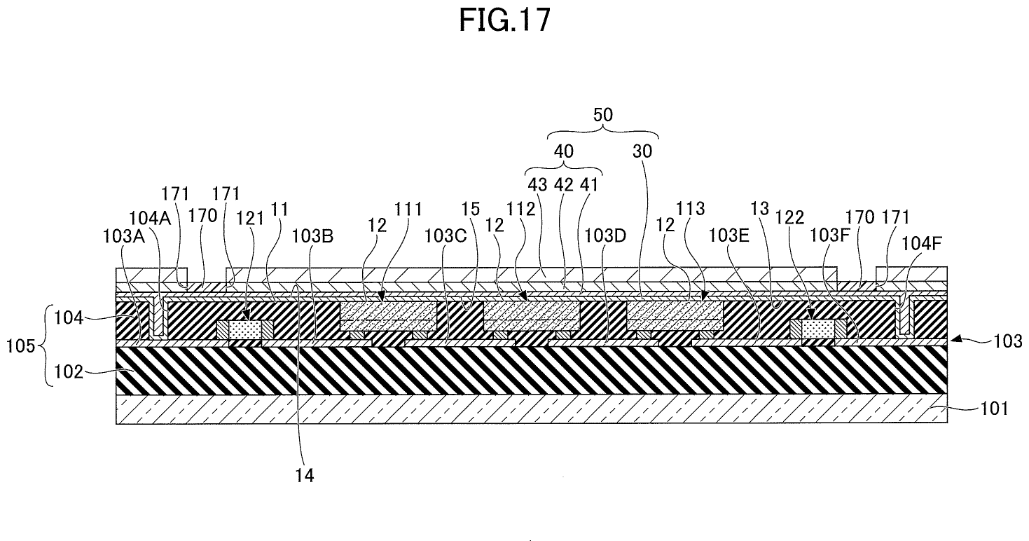

An electroplated layer 43 is then formed on the electroplated layer 42 by electroplating, as shown in FIG. 17. As the electroplated layer 43, for example, a Cu layer is formed. The electroplated layer 43 is preferably formed at a deposition rate of 50 μm/hour or more, and more preferably at a deposition rate of 60 μm/hour or more. The electroless plated layer 41, the electroplated layer 42, and the electroplated layer 43 are included in the plated layer 40. The sputtered layer 30 and the plated layer 40 are included in the heat dissipation layer 50. The thickness of the heat dissipation layer 50 is preferably 100 μm or more, more preferably 200 μm or more, and still more preferably 300 μm or more.

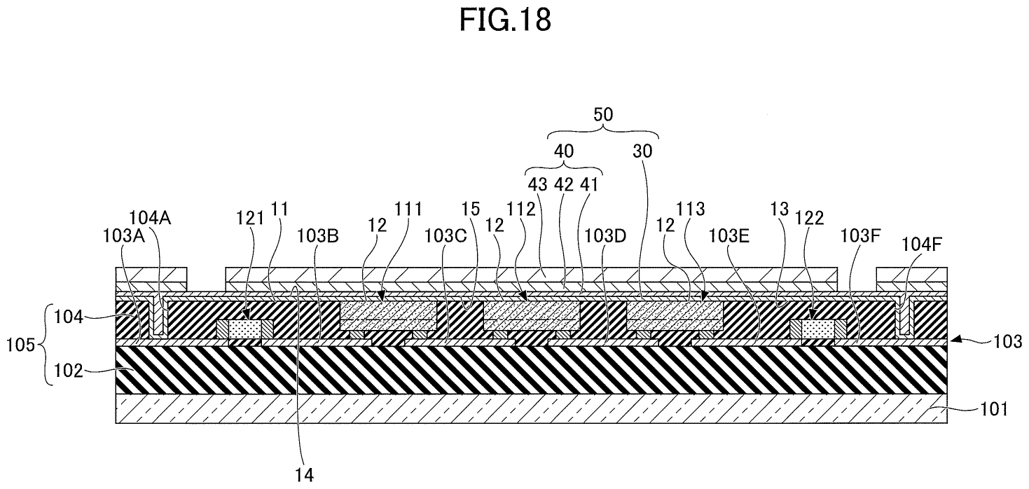

Next, as shown in FIG. 18, the growth mask 170 is removed.

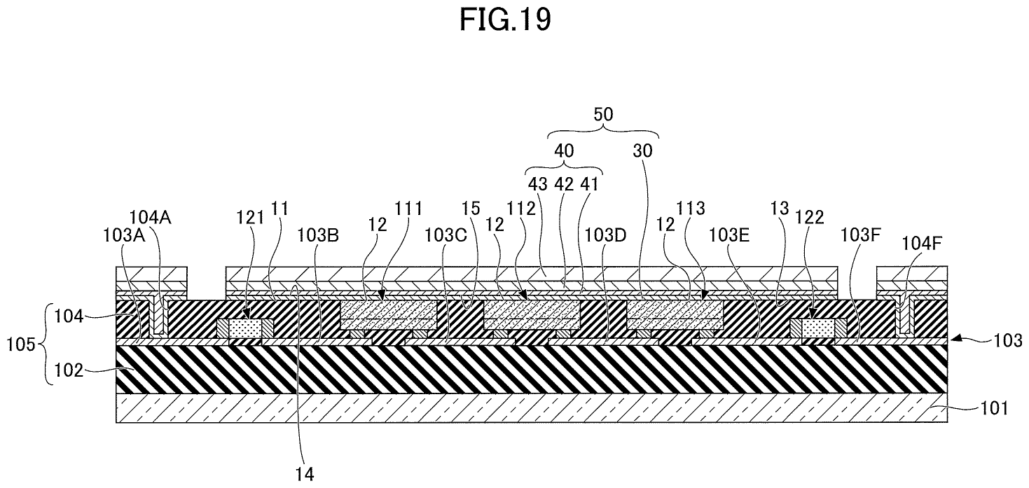

As shown in FIG. 19, the portion exposed from the electroplated layer 43 among the stacked body of the sputtered layer 30 and the electroless plated layer 41 is removed by quick etching or the like.

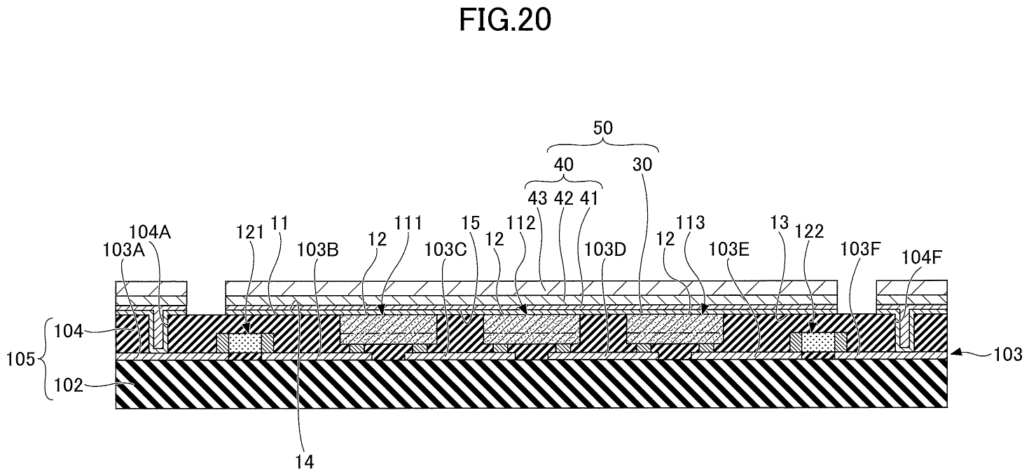

A substrate 101 is then removed, as shown in FIG. 20. Thereafter, the structure shown in FIG. 20 is cut along a dicing region to be separated into a plurality of semiconductor devices 1.

In this manner, the semiconductor device 1 according to the first embodiment can be obtained.

### (Effect of Semiconductor Device)

The semiconductor chips 111 to 113 generate heat when the semiconductor device 1 is activated. In the first embodiment, since the heat dissipation layer 50 is formed on the first surface 11 and the second surface 12, the heat generated by the semiconductor chips 111 to 113 is transferred to the heat dissipation layer 50. The heat transferred to the heat dissipation layer 50 is dissipated to the outside. In the first embodiment shown in FIG. 2, the heat is transferred to the base metal 71 through the conductive vias 62 and is dissipated to the surrounding ambience. In the first embodiment, since the heat dissipation layer 50 includes the plated layer 40, an excellent adhesion can be obtained between the heat dissipation layer 50 and the semiconductor chips 111 to 113. Therefore, the heat generated by the semiconductor chips 111 to 113 can be stably transferred to the heat dissipation layer 50. Therefore, according to the first embodiment, stable heat dissipation characteristics can be obtained. The conductive bonding material 72, the mother substrate 60 and the base metal 71 are examples of a heat dissipation member.

In the first embodiment, the sputtered layer 30 is provided between the plated layer 40 and the semiconductor chips 111 to 113. In forming the sputtered layer 30, particles of raw materials constituting the sputtered layer 30 collide with the first surface 11 and the second surface 12 with a high energy to form the sputtered layer 30, thereby the third surface 13 of the sputtered layer 30 is firmly bonded to the first surface 11 and the second surface 12. Therefore, the heat transfer efficiency from the semiconductor chips 111 to 113 to the heat dissipation layer 50 is excellent.

In the first embodiment, the electroless plated layer 41 is formed on the sputtered layer 30. The electroless plated layer 41 has a good adhesion with the sputtered layer 30. The electroless plated layer 41 can function as a seed layer for the electroplated layer 42.

In the first embodiment, the electroplated layer 42 is formed on the electroless plated layer 41. The electroplated layer 42 is easier to form thick than the electroless plated layer 41. Therefore, a good heat dissipation can be obtained by forming the electroplated layer 42.

When the electroplated layer 42 is formed relatively thick, the thickness of the electroplated layer 42 may vary. In particular, the larger the substrate 101, the more easily the thickness of the electroplated layer 42 varies. The variation in thickness of the electroplated layer 42 can lead to a variation in heat resistance. In the first embodiment, since the top surface of the electroplated layer 42 is polished after the electroplated layer 42 is formed, the variation in thickness of the heat dissipation layer 50 can be suppressed, the uniformity of the thickness of the heat dissipation layer 50 can be improved, and the uniformity of heat resistance can be improved.

In the first embodiment, the electroplated layer 43 is formed on the electroplated layer 42. The electroplated layer 43 may be formed under conditions distinct from the electroplated layer 42. For example, the electroplated layer 43 may be formed under the conditions in which the deposition rate becomes higher than that of the electroplated layer 42. In this case, excellent heat dissipation characteristics can be obtained in a short time.

Furthermore, the semiconductor device according to the first embodiment is superior to a semiconductor device in which a metal plate is attached, in terms of costs. When a metal plate is used, a silver nano paste or the like is used for bonding an insulating layer and the metal plate. Also, a thermal via may be formed in the insulating layer. Moreover, a metal plate is expensive. In contrast, in the first embodiment, since the heat dissipation layer 50 only includes the sputtered layer 30 and the plated layer 40, it can be produced at a lower cost than a semiconductor device to which a metal plate is attached.

The semiconductor device 1 can be used, for example, in base stations of the fifth generation mobile communication system, the so-called 5G. Since the semiconductor chips 111 to 113 are constructed using a silicon carbide substrate 20, the semiconductor device 1 is suitable for high-frequency applications. For example, it can be used for a 5G module with an antenna for 28 GHz band. Power consumption of the 5G module is about 3 W to 10 W, and the semiconductor device 1 can sufficiently dissipate heat generated by the semiconductor chips 111 to 113 to the outside.

The semiconductor device 1 can also be used, for example, in a 140-GHz band radar module. Power consumption of the radar module is about 0.5 W, and according to the semiconductor device 1, heat generated by the semiconductor chips 111 to 113 can be sufficiently dissipated to the outside.

The semiconductor device 1 can also be used, for example, in a high-power high-frequency (RF) device. Power consumption of the high-power high-frequency device is about 100 W, and according to the semiconductor device 1, it is possible to sufficiently dissipate heat generated by the semiconductor chips 111 to 113 to the outside.

### Second Embodiment of Present Disclosure

A second embodiment relates to a semiconductor device.

(Structure of Semiconductor Device)

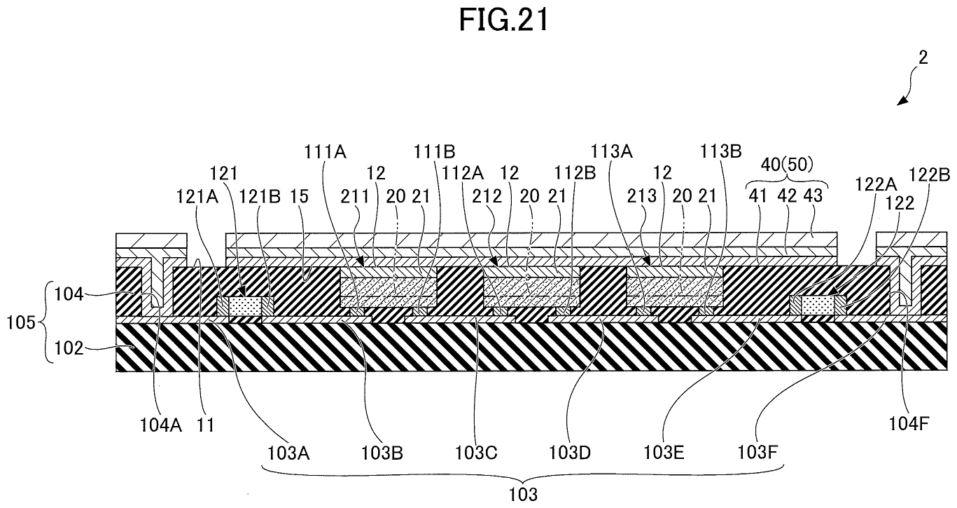

First, the structure of a semiconductor device according to the second embodiment will be described. FIG. 21 is a cross-sectional view showing the structure of a semiconductor device according to the second embodiment.

As shown in FIG. 21, in a semiconductor device 2 according to the second embodiment, semiconductor chips 211, 212, and 213 are provided instead of the semiconductor chips 111, 112, and 113 according to the first embodiment. Similar to the semiconductor chip 111, the semiconductor chip 211 includes an electrode 111A, an electrode 111B, and a silicon carbide substrate 20, and further includes a Cu layer 21 in contact with silicon carbide substrate 20. The second surface 12 is not provided on the silicon carbide substrate 20 but on the Cu layer 21. Similar to the semiconductor chip 112, the semiconductor chip 212 includes an electrode 112A, an electrode 112B, and a silicon carbide substrate 20, and further includes a Cu layer 21 in contact with silicon carbide substrate 20. The second surface 12 is not provided on the silicon carbide substrate 20 but on the Cu layer 21. Similar to the semiconductor chip 113, the semiconductor chip 213 includes an electrode 113A, an electrode 113B, and a silicon carbide substrate 20, and further includes a Cu layer 21 in contact with silicon carbide substrate 20. The second surface 12 is not provided on the silicon carbide substrate 20 but on the Cu layer 21. Similar to the semiconductor chips 111 to 113, the semiconductor chips 211 to 213 are embedded in the insulating substrate 105.

The Cu layer 21 can be formed, for example, at the time of forming each of the semiconductor chips 211, 212, and 213, by attaching, with an Ag paste or the like, a Cu layer to the back surface of a silicon carbide wafer to be the silicon carbide substrate 20 and separating the Cu layer together with the silicon carbide wafer. Also, the semiconductor chips 211 to 213 may be formed by attaching the Cu layer 21 to each of the semiconductor chips 111 to 113 according to the first embodiment with an Ag paste or the like.

The heat dissipation layer 50 has a plated layer 40 having a fifth surface 15 in contact with the first surface 11 and the second surfaces 12. The plated layer 40 includes, for example, an electroless plated layer 41 formed on the insulating layer 104 and the Cu layers 21, an electroplated layer 42 formed on the electroless plated layer 41, and an electroplated layer 43 formed on the electroplated layer 42. The electroless plated layer 41 includes a Cu layer having the fifth surface and having a thickness of 0.1 μm or more and 10 μm or less, for example. The electroplated layer 42 includes a Cu layer having a thickness of 50 μm or more and 90 μm or less, for example. The electroplated layer 43 includes a Cu layer, for example. The total thickness of the electroless plated layer 41 and the electroplated layer 42 is preferably 100 μm or less, more preferably 80 μm or less, for example.

Other configurations are similar to those of the first embodiment.

### First Example of Method for Producing Semiconductor Device According to Second Embodiment

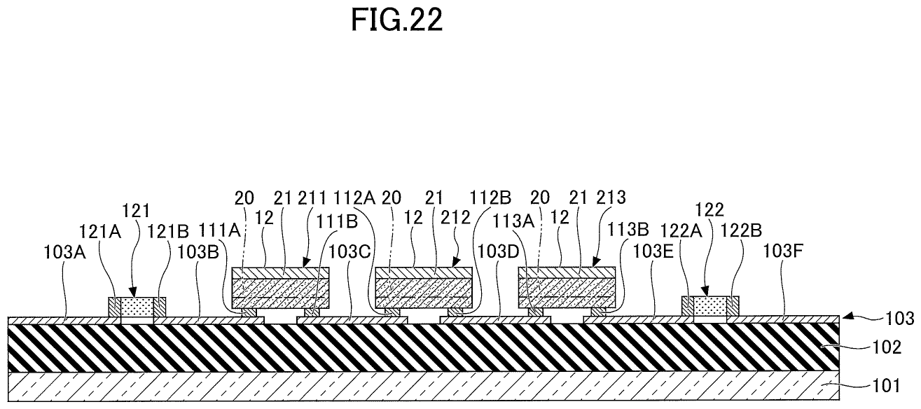

Next, a first example of a method for producing a semiconductor device according to the second embodiment will be described. FIG. 22 to FIG. 27 are cross-sectional views illustrating a first example of a method for producing a semiconductor device according to the second embodiment.

First, as shown in FIG. 22, processes up to the forming of a wiring layer 103 is performed in the same manner as the first example according to the first embodiment. Semiconductor chips 211, 212, and 213 are then mounted on the wiring layer 103. At this time, the semiconductor chips 211 to 213 are mounted such that each second surface 12 faces the direction opposite the direction towards the insulating layer 102. That is, the semiconductor chips 211, 212, and 213 are mounted with flip-chip bonding. For example, an electrode 111A of a semiconductor chip 211 is connected to a wiring 103B, and an electrode 111B is connected to a wiring 103C. For example, an electrode 112A of a semiconductor chip 212 is connected to the wiring 103C, and an electrode 112B is connected to a wiring 103D. For example, an electrode 113A of a semiconductor chip 213 is connected to the wiring 103D and an electrode 113B is connected to the wiring 103E.

Further, electronic components 121 and 122 are mounted on the wiring layer 103 in the same manner as the first example according to the first embodiment.

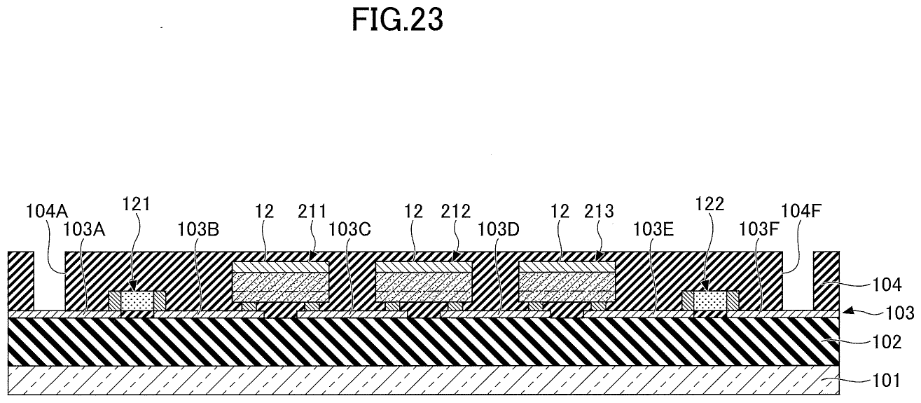

Then, as shown in FIG. 23, in the same manner as the first example in the first embodiment, an insulating layer 104 is formed, and an opening 104A reaching the wiring 103A and an opening 104F reaching the wiring 103F in the insulating layer 104.

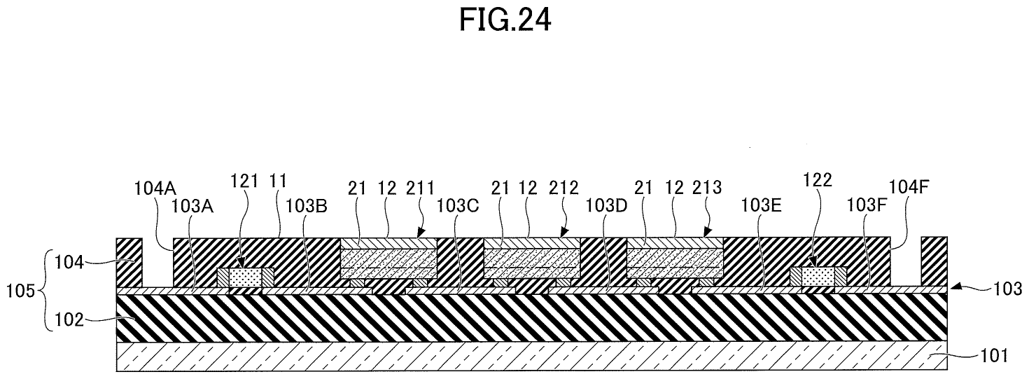

Next, as shown in FIG. 24, the top surface of the insulating layer 104 is polished until each of the second surfaces 12 of the semiconductor chips 211 to 213 is exposed. As a result, a first surface 11 is provided in the insulating layer 104. The arithmetic average roughness (Ra) of the first surface 11 is preferably 2.0 μm or less, more preferably 1.6 μm or less, and still more preferably 1.0 μm or less. This is to obtain an excellent flatness of a heat dissipation layer 50 to be formed later. The first surface 11 is preferably flush with the second surfaces 12. The insulating layer 102 and the insulating layer 104 are included in an insulating substrate 105 having the first surface 11.

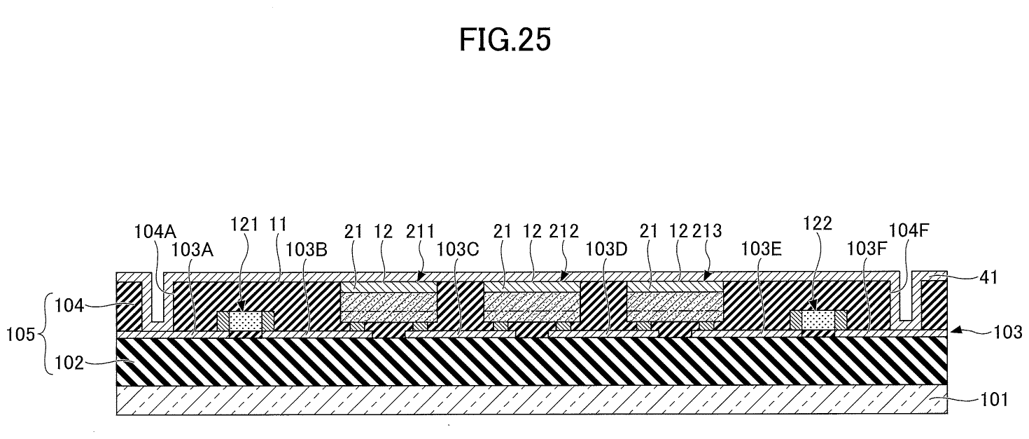

An electroless plated layer 41 is then formed on the top surface of the insulating layer 104 and the inner wall and bottom surfaces of the openings 104A and 104F, by electroless plating, as shown in FIG. 25. The electroless plated layer 41 has a fifth surface 15 in contact with the first surface 11 and the second surfaces 12. Prior to forming the electroless plated layer 41, a desmear treatment may be performed to the top surface of the insulating layer 104 and the inner wall and bottom surfaces of the openings 104A and 104F. After the desmear treatment, a catalyst treatment or the like may be performed.

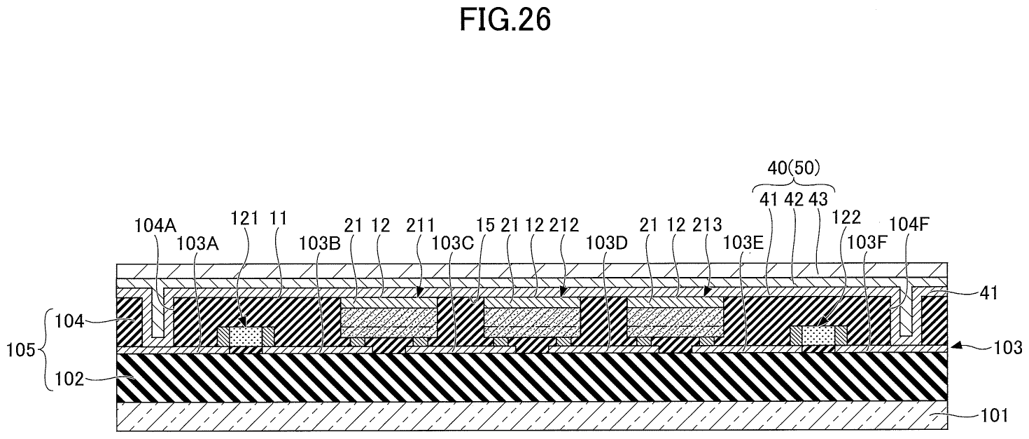

Then, as shown in FIG. 26, similar to the first example of the first embodiment, an electroplated layer 42 is formed on the electroless plated layer 41 by an electroplating method and an electroplated layer 43 is formed on the electroplated layer 42 by an electroplating method.

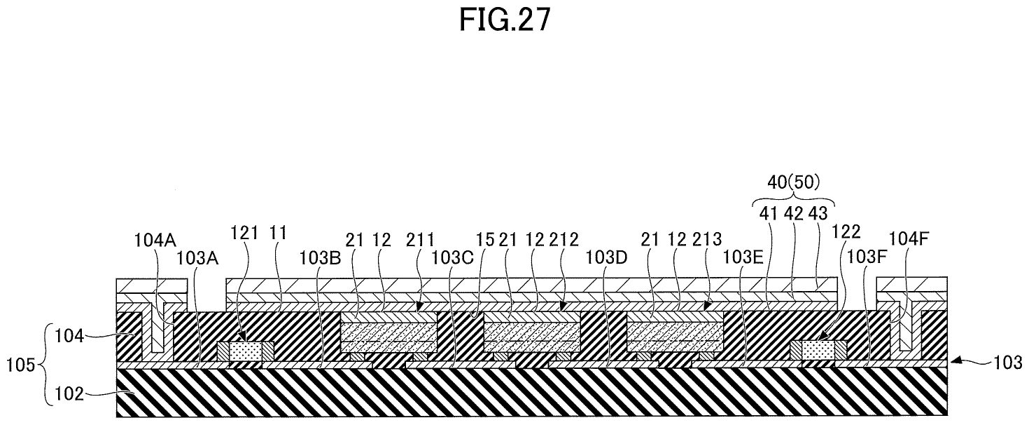

Thereafter, as shown in FIG. 27, the etching mask 160 is formed, the heat dissipation layer 50 is etched, and the substrate 101 is removed in the same manner as the first example according to the first embodiment. Thereafter, the structure shown in FIG. 27 is cut along a dicing region to be separated into a plurality of semiconductor devices 2.

In this manner, the semiconductor device 2 according to the second embodiment can be obtained.

### Second Example of Method for Producing Semiconductor Device According to Second Embodiment

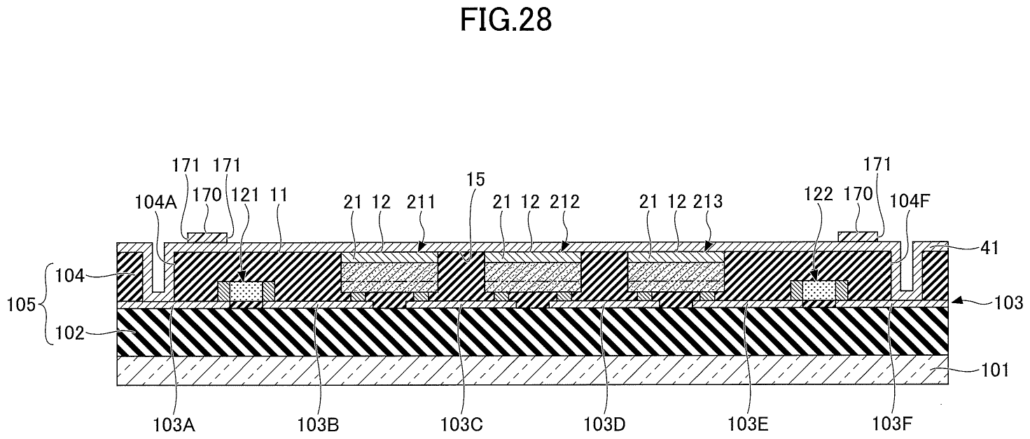

Next, a second example of a method for producing a semiconductor device according to the second embodiment will be described. FIGS. 28 to 30 are cross-sectional views showing the second example of a method for producing a semiconductor device according to the second embodiment.

First, as shown in FIG. 28, in the same manner as in the first example of the second embodiment, the steps up to the forming of an electroless plated layer 41 is performed. Next, in the same manner as in the second example of the first embodiment, a growth mask 170 is formed on the electroless plated layer 41. The growth mask 170 has openings 171 on the portions on which a heat dissipation layer 50 is to be formed.

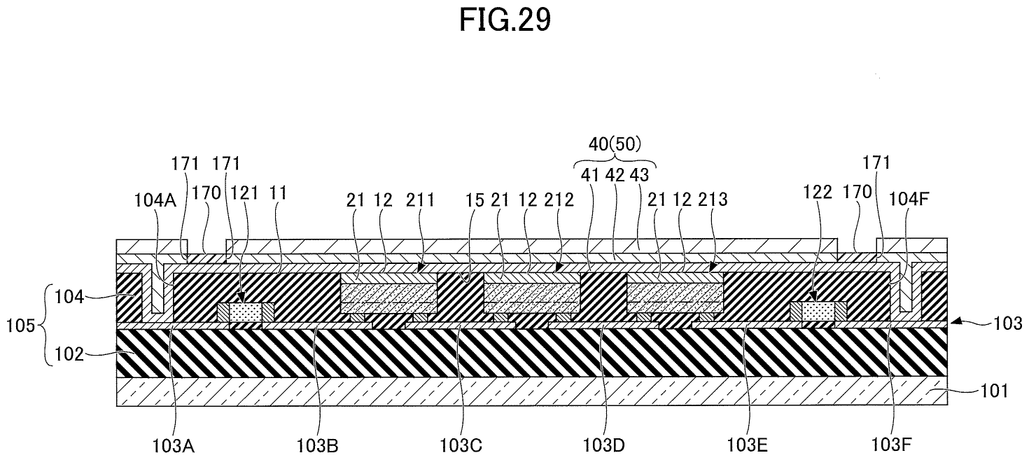

Next, as shown in FIG. 29, in the same manner as in the second example of the first embodiment, an electroplated layer 42 is formed on the electroless plated layer 41 by electroplating, and an electroplated layer 43 is formed on the electroplated layer 42 by electroplating.

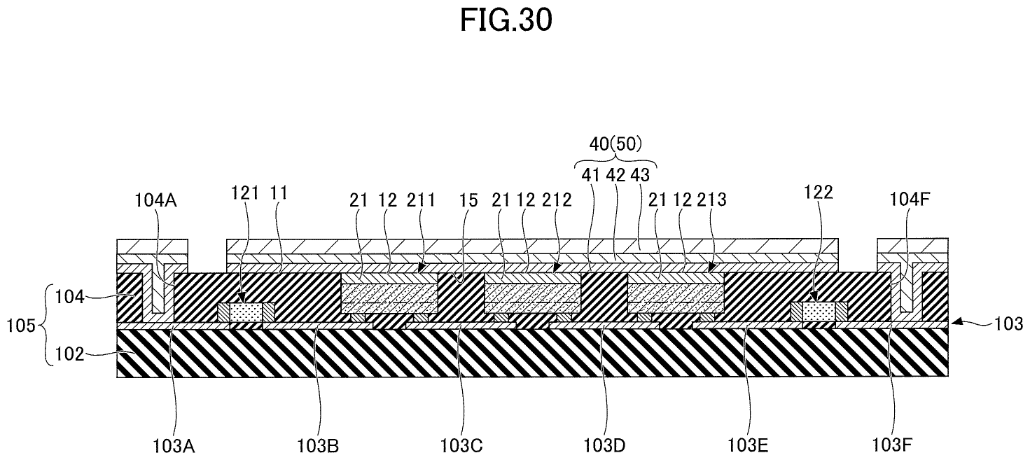

Then, as shown in FIG. 30, in the same manner as the second example of the first embodiment, the growth mask 170 is removed, the portions of the electroless plated layer 41 exposed from the electroplated layer 43 are removed, and the substrate 101 is removed. Thereafter, the structure shown in FIG. 30 is cut along a dicing region to be separated into a plurality of semiconductor devices 2.

In this manner, the semiconductor device 2 according to the second embodiment can be obtained.

### Effect of Semiconductor Device According to Second Embodiment

In the second embodiment, since the heat dissipation layer 50 includes the plated layer 40, an excellent adhesion can be obtained between the heat dissipation layer 50 and the semiconductor chips 211 to 213. Therefore, the heat generated by the semiconductor chips 211 to 213 can be stably transferred to the heat dissipation layer 50. Therefore, according to the second embodiment, stable heat dissipation characteristics can be obtained.

In the first embodiment, each of the semiconductor chips 211 to 213 includes the Cu layer 21 having the second surface 12. That is, the Cu layers 21 contact the plated layer 40. Accordingly, even though the sputtered layer 30 in the first embodiment is not provided, the fifth surface of the plated layer 40 is firmly bonded to the first surface 11 and the second surfaces 12. Therefore, the heat transfer efficiency from the semiconductor chips 211 to 213 to the heat dissipation layer 50 is excellent.

Effects similar to the effects of the first embodiment can also be obtained by the second embodiment.

Also, because the sputtered layer 30 according to the first embodiment is not included, the productivity can be enhanced. That is, although a deposition chamber is made vacuum when forming a sputtered layer 30, in a case in which an organic material such as a dry film is used for the insulating layer 102 and the insulating layer 104, it may take a long time to make the deposition chamber vacuum. By omitting the formation of the sputtered layer 30, the productivity can be enhanced without the need for processing under vacuum.

The embodiments of the present disclosure have been described above. However, the embodiments of the present disclosure disclosed above are only illustrative, and the scope of the present invention is not limited to the specific embodiments of the disclosure. It is to be understood that the scope of the present invention is defined in the appended claims and includes equivalence of the description of the claims and all changes within the scope of the claims.

What is claimed is:

1. A semiconductor device comprising:
an insulating substrate having a first surface,
a semiconductor chip embedded in the insulating substrate and having a second surface exposed in the first surface, and
a heat dissipation layer that is in contact with the first surface and the second surface and having a plated layer.

2. The semiconductor device according to claim 1, wherein the heat dissipation layer includes a sputtered layer having a third surface in contact with the first surface and the second surface, and a fourth surface opposite to the third surface, and the plated layer includes a fifth surface in contact with the fourth surface.

3. The semiconductor device according to claim 1, wherein the semiconductor chip includes a silicon carbide substrate having the second surface.

4. The semiconductor device according to claim 1,
wherein the semiconductor chip includes
a silicon carbide substrate, and
a Cu layer in contact with the silicon carbide substrate and having the second surface,
wherein the plated layer has a fifth surface in contact with the first surface and the second surface.

5. The semiconductor device according to claim 1, wherein a thickness of the heat dissipation layer is 100 μm or more.

6. The semiconductor device according to claim 1, wherein a heat dissipation member is attached to the heat dissipation layer.

7. A method for producing a semiconductor device comprising:
embedding a semiconductor chip having a second surface to be exposed in a first surface into an insulating substrate having the first surface, and
forming a heat dissipation layer that is in contact with the first surface and the second surface and having a plated layer.

8. The method for producing a semiconductor device according to claim 7,
wherein the insulating substrate includes a first insulating layer and a second insulating layer, and
the embedding a semiconductor chip includes:
forming a wiring layer on the first insulating layer,
mounting the semiconductor chip on the wiring layer such that the second surface faces a direction opposite a direction towards the first insulating layer,
forming the second insulating layer on the first insulating layer so as to cover the semiconductor chip, and
providing the first surface in the second insulating layer by polishing the second insulating layer until the second surface is exposed.

9. The method for producing a semiconductor device according to claim 7,
wherein the forming a heat dissipation layer includes:
forming a sputtered layer having a third surface in contact with the first surface and the second surface, and a fourth surface opposite to the third surface, and
forming the plated layer on the sputtered layer, the plated layer including a fifth surface in contact with the fourth surface.

10. The method for producing a semiconductor device according to claim 9, wherein the forming a plated layer includes forming a first layer having the fifth surface on the sputtered layer by electroless plating.

11. The method for producing a semiconductor device according to claim 7,
wherein the semiconductor chip includes a Cu layer having the second surface, and
wherein the forming a heat dissipation layer includes forming the plated layer to be in contact with the first surface and the second surface.

12. The method for producing a semiconductor device according to claim 11, wherein the forming a plated layer includes forming a first layer in contact with the first surface and the second surface by electroless plating.

13. The method for producing a semiconductor device according to claim 10, wherein the forming a plated layer includes forming a second layer on the first layer by electroplating.

14. The method for producing a semiconductor device according to claim 13, wherein the forming a plated layer includes polishing the second layer.

15. The method for producing a semiconductor device according to claim 13, wherein the forming a plated layer includes forming a third layer on the second layer by electroplating.

16. A method for producing a semiconductor device comprising:
forming a wiring layer on a first insulating layer,
mounting a semiconductor chip having a second surface on the wiring layer such that the second surface faces a direction opposite a direction towards the first insulating layer,
forming a second insulating layer on the first insulating layer so as to cover the semiconductor chip,
providing a first surface in the second insulating layer by polishing the second insulating layer until the second surface is exposed,
forming a sputtered layer having a third surface in contact with the first surface and the second surface, and a fourth surface opposite to the third surface, and
forming a plated layer having a fifth surface in contact with the fourth surface on the sputtered layer,
wherein the forming a plated layer includes forming a first layer having the fifth surface on the sputtered layer by electroless plating,
forming a second layer on the first layer by electroplating,
polishing the second layer, and
forming a third layer on the second layer by electroplating after the polishing the second layer.

17. A method for producing a semiconductor device, the method comprising:
forming a wiring layer on a first insulating layer;
mounting a semiconductor chip including a Cu layer having a second surface on the wiring layer such that the second surface faces a direction opposite a direction towards the first insulating layer;
forming a second insulating layer on the first insulating layer so as to cover the semiconductor chip;
providing a first surface in the second insulating layer by polishing the second insulating layer until the second surface is exposed; and
forming a plated layer to be in contact with the first surface and the second surface,
wherein the forming the plated layer includes
forming a first layer in contact with the first surface and the second surface by electroless plating,
forming a second layer on the first layer by electroplating,
polishing the second layer, and
forming a third layer on the second layer by electroplating after the polishing the second layer.
